(19) United States
(12) Patent Application Publication
(10) Pub. No.: US 2025/0275105 A1
(43) Pub. Date: Aug. 28, 2025

(54) DISPLAY APPARATUS

(71) Applicant: LG Display Co., Ltd., Seoul (KR)

(72) Inventors: Inwoo Kwon, Suwon-si (KR); Byoungjin Jeon, Paju-si (KR)

(73) Assignee: LG Display Co., Ltd., Seoul (KR)

(21) Appl. No.: 18/749,783

(22) Filed: Jun. 21, 2024

(30) Foreign Application Priority Data
Feb. 26, 2024 (KR) 10-2024-0027012

(51) Int. Cl. H05K 7/20; G06F 1/16

(52) U.S. Cl. CPC H05K 7/20963; G06F 1/1656

(57) ABSTRACT

A display apparatus according to one embodiment may include a display unit configured to display an image, a holder disposed above the display unit and provided in a plate shape, a control assembly disposed above the holder and including a control board and a control chip mounted on an upper surface of the control board, a shield cover disposed above the control assembly, a heat transfer member disposed above the shield cover and in contact with a portion of the shield cover, a back cover disposed above the heat transfer member and in contact with at least a portion of the heat transfer member, and a support member attached to the holder, configured to support the control board, and vertically separate the control assembly and the holder.

### CROSS REFERENCE TO RELATED APPLICATION

The present application claims priority to Korean Patent Application No. 10-2024-0027012, filed Feb. 26, 2024, the entire contents of which is incorporated herein for all purposes by this reference.

### BACKGROUND

### Technical Field

The present disclosure relates to a display apparatus, and more specifically, to a display apparatus having an effective heat dissipation structure.

### Discussion of the Related Art

Contents described in this section simply provide background information on the present disclosure and do not constitute the related art.

In the full-fledged information age, the field of display apparatuses for visually displaying electrical information signals is developing rapidly, and research for developing performance, such as thinness, lightweight, and lower power consumption, for various display apparatuses is being continuously conducted.

Such display apparatuses include a liquid crystal display (LCD) device, a quantum dot display panel device (QD), a field emission display (FED) device, and an electro-wetting display (EWD) device, an organic light emitting diode (OLED) display apparatus, etc.

The display apparatuses have been developed to be miniaturized so that users may carry the display apparatuses or to be mounted on movable devices such as vehicles, etc., and are being improved so that the users may use the display apparatuses more conveniently.

### SUMMARY

A display apparatus may be provided with chips and elements that have high heat generation capacity, and a board including the chips and the elements therein. Heat may be generated in the display apparatus due to heating components, and the excessive heating may have a negative effect on the display apparatus.

With a current technological trend, the development of thin display apparatuses having an overall small thickness is accelerating for user convenience.

When excessive heat is generated due to the heating components in such a thin display apparatus, the heat generated from any one heating component is easily transferred to other components due to the close distance to other components due to the thin structure to cause overheating of the component receiving the heat, thereby degrading performance and in severe cases, causing failure.

In particular, when heat is transferred to a display unit in which an image is displayed of the display apparatus, various elements, a light source, pixels, etc. provided inside the display unit may be affected by the overheating of the display unit, thereby degrading image quality or degrading various other performance. Therefore, there is a need to develop a structure that can suppress the heat transfer from the heating component to the display unit.

Meanwhile, the display apparatus may have a structure in which heat transfer members made of a material having high thermal conductivity are in contact with each other so that heat generated from the heating components is easily transferred to the external atmosphere to cool the display apparatus.

The heat conducted by the heat transfer member may be ultimately transferred to components disposed at the outermost portion of the display apparatus, and the outermost portion may serve as a heat sink to transfer heat to the atmosphere, thereby suppressing overheating of the display apparatus.

Due to heating, the components constituting the display apparatus may be deformed by heat. Due to the thermal deformation of the components, the heat transfer member may be spaced apart from the heating component to prevent at least portion thereof from being in contact with the display apparatus, thereby degrading the heat dissipation performance of the display apparatus.

It is necessary to solve such a problem.

Accordingly, embodiments of the present disclosure are directed to a display apparatus that substantially obviates one or more of the problems due to limitations and disadvantages of the related art.

An aspect of the present disclosure is to provide a display apparatus including a structure capable of suppressing heat transfer from a heating component to a display unit.

Another aspect of the present disclosure is to provide a display apparatus including a structure capable of increasing heat dissipation performance by maintaining contact between a heat transfer member and a heating component even when thermal deformation due to heating occurs.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus may comprise a display unit configured to display an image, a holder disposed above the display unit and provided in a plate shape, a control assembly disposed above the holder and including a control board and a control chip mounted on an upper surface of the control board, a shield cover disposed above the control assembly, a heat transfer member disposed above the shield cover and in contact with a portion of the shield cover, a back cover disposed above the heat transfer member and in contact with at least a portion of the heat transfer member, and a support member attached to the holder, configured to support the control board, and vertically separate the holder and the control assembly.

The support member may include a base attached to the holder, a rotation supporter rotatably coupled to the base to support the control board, and a coupling pin rotatably coupling the rotation supporter with the base.

The rotation supporter may include a coupling cell which is coupled to the shield cover and on which the coupling pin is mounted, and a support cell extending from the coupling cell to support a lower surface of the control board.

When the control assembly is heated, the control board may laterally expand to rotate the rotation supporter, and the rotation supporter may move the control assembly by pressing the lower surface of the control board.

When the control assembly is heated, the rotation supporter may maintain contact between the control assembly, the shield cover, the heat transfer member, and the back cover by moving the control assembly up.

When the control assembly is heated, the control board may laterally expand to rotate the coupling cell, and the support cell may rotate together with the rotation of the coupling cell.

When the control assembly is heated, the support cell may rotate to press the lower surface of the control board and move the control board up.

The support cell may maintain contact between the control assembly, the shield cover, the heat transfer member, and the back cover by moving the control assembly up.

In the display apparatus according to the present disclosure, the support member may be attached to the holder, configured to support the control board, and vertically separate the control assembly and the holder.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a perspective view showing a display apparatus according to one embodiment.

FIG. 2 is an exploded view of FIG. 1.

FIG. 3 is a front view showing the display apparatus according to one embodiment.

FIG. 4 is an enlarged view of a portion of FIG. 3.

FIG. 5 is an enlarged view of another portion of FIG. 3.

FIG. 6 is a view in which some components of the display apparatus according to one embodiment have been omitted.

FIG. 7 is an enlarged view of a portion in which an insertion groove is formed of a shield cover according to one embodiment.

FIG. 8 is a perspective view showing a support member according to one embodiment.

FIG. 9 is a view of FIG. 8 in another direction.

FIG. 10 is a view for describing a support member according to another embodiment.

FIG. 11 is a view for describing deformation caused by heat deformation in the display apparatus when there is no support member.

FIG. 12 is a view for describing an operation of the support member according to one embodiment.

FIG. 13 is a view for describing an operation of the support member when a control assembly is thermally deformed in FIG. 12.

FIG. 14 is a view for describing an operation of a support member according to another embodiment.

FIG. 15 is a view for describing an operation of the support member when a control assembly is thermally deformed in FIG. 14.

### DETAILED DESCRIPTION

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary embodiments according to the present disclosure will be described in detail with reference to the accompanying drawings. In the drawings, the same reference numerals are used to denote the same or similar components.

Although terms such as first and second are used to describe various components, it goes without saying that the components are not limited by these terms. These terms are only used to distinguish one component from another component, and unless otherwise stated, it goes without saying that the first component may be the second component.

Throughout the specification, unless otherwise stated, each component may be singular or plural.

The singular expression used herein includes the plural expression unless the context clearly dictates otherwise. In the application, terms such as “composed of” or “comprising” should not be construed as necessarily including all of the various components or operations described in the specification and should be construed as not including some of the components or some of the operations or further including additional components or operations.

Throughout the specification, when “A and/or B” is described, this means A, B, or A and B unless otherwise specified, and when “C to D” is described, this means C or more and D or less unless otherwise specified.

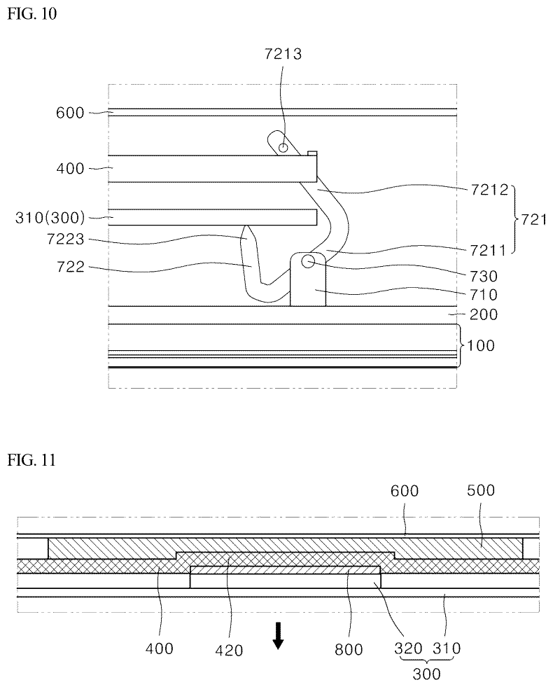

Directions referred to as top, bottom, upper side, and lower side in the specification are based on a direction of a display apparatus shown in FIGS. 4 and 10 and may also be referred to as top, bottom, upper side, and lower side in other drawings disposed in the same direction as these drawings.

In an embodiment, when the display apparatus is mounted in a state of daily use, the lower side in each drawing may be a front surface front of the display apparatus, and the upper side may be a back surface of the display apparatus.

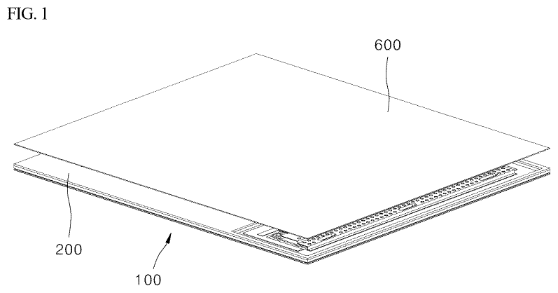

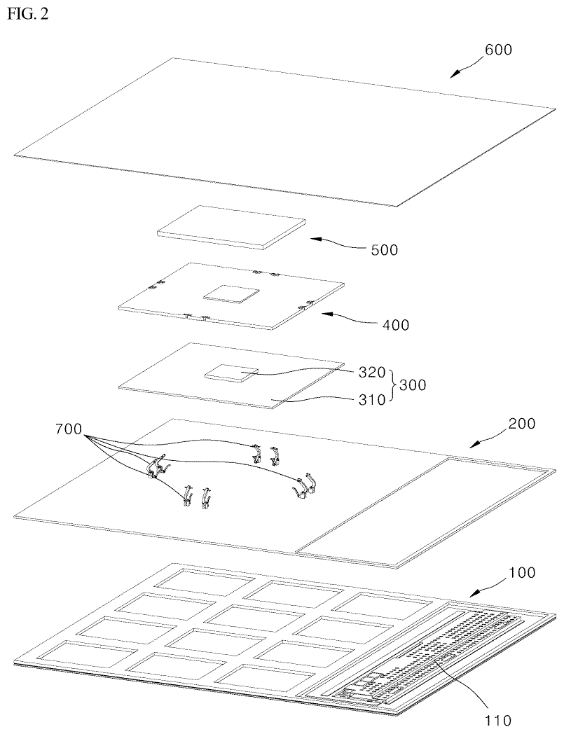

FIG. 1 is a perspective view showing a display apparatus according to one embodiment. FIG. 2 is an exploded view of FIG. 1. The display apparatus may include a display unit 100, a holder 200, a control assembly 300, a shield cover 400, a heat transfer member 500, a back cover 600, and a support member 700.

The display unit 100 may display an image. The display unit 100 may include a panel in which pixels that display the image are implemented, a cover glass for protecting the panel, a light source for radiating light to the panel, and other components for displaying the image.

The display unit 100 may include a socket 110 generally formed in a plate shape and provided with a cable for electrical connection with the control assembly 300 and/or a power source. The socket 110 may be provided with a protrusion.

The holder 200 may be disposed above the display unit 100 and provided in a plate shape. The holder 200 may cover an upper surface of the display unit 100 to protect internal components of the display unit 100 and at the same time, have an upper surface attached to the support member 700.

The control assembly 300 may be disposed above the holder 200 and may include a control board 310 and a control chip 320 mounted on an upper surface of the control board 310. The control assembly 300 may control an operation of the display unit 100.

The control board 310 may be provided in a plate shape, and the control chip 320 may be mounted to have a portion protruding from the upper surface of the control board 310. The control chip 320 may include, for example, an integrated circuit and other active and passive elements.

The control board 310 may be provided with various active elements, passive elements, and electric circuits for driving the control chip 320. A controller for controlling the operation of the display unit 100 may be implemented on the control chip 320 and the control board 310.

In this case, the control chip 320 may be provided as, for example, a field programmable gate array (FPGA) chip. The FPGA is a semiconductor element including designable logic elements and programmable internal circuits. However, the present disclosure is not limited thereto.

The control chip 320 and the control board 310 may control the operation of the display unit 100 and may be operated by receiving electricity from an external power source to generate heat. In particular, since the control chip 320 and the control board 310 are provided with relatively large heating elements due to an operation using electricity, the control assembly 300 including the control chip 320 and the control board 310 may generate more heat than the display unit 100.

To dissipate the heat generated from the control chip 320 to the outside of the display apparatus, the display apparatus may be provided with a structure that transfers heat from the control chip 320 to the back cover 600 by conduction. This will be described in detail below.

The shield cover 400 may be disposed above the control assembly 300 and may be provided to be in contact with the control chip 320. The control chip 320 and the shield cover 400 may be coupled by using an adhesive pad 800 to be described below. The heat generated from the control chip 320 may be transferred to the shield cover 400 by conduction.

The shield cover 400 may be provided substantially in a plate shape and may cover an upper surface of the control assembly 300 to protect the control assembly 300. In particular, the shield cover 400 may cover the control chip 320 disposed on the upper surface of the control board 310 to block external electromagnetic waves from flowing into the control chip 320, thereby effectively suppressing the defective operation of the control chip 320 due to the electromagnetic waves.

Likewise, the shield cover 400 may cover at least a portion of the upper surface of the control board 310 to protect the entirety of the control assembly 300 from electromagnetic waves, thereby effectively suppressing the defective operation of the control assembly 300 due to the electromagnetic waves.

The shield cover 400 can effectively block the electromagnetic waves and at the same time, may be made of a material having high thermal conductivity. Therefore, the shield cover 400 may be made of a metal material, such as aluminum, copper, or a material containing aluminum or copper, or magnesium or a material containing magnesium.

The heat transfer member 500 may be provided in a plate shape, disposed above the shield cover 400, and may be in contact with a portion of the shield cover 400. The heat transfer member 500 may be formed to have a smaller area than the shield cover 400.

The heat transfer member 500 may be disposed between the shield cover 400 and the back cover 600 to transfer heat from the shield cover 400 to the back cover 600. Therefore, it is appropriate that the heat transfer member 500 is made of a material having high thermal conductivity.

The heat transfer member 500 may be made of, for example, thermal interface materials (TIM) that are high thermal conductivity and are highly effective in dissipating heat of chips in electronic and electrical products. However, the present disclose is not limited thereto.

The back cover 600 may be disposed above the heat transfer member 500 and may be in contact with at least a portion of the heat transfer member 500. The back cover 600 may be provided in a plate shape to have an area corresponding to the display unit 100 and formed to have a greater area than the heat transfer member 500.

The back cover 600 can protect the display apparatus and at the same time, may emit heat transferred from the heat transfer member 500 to the atmosphere. Therefore, the back cover 600 may be made of a metal material having high thermal conductivity, such as aluminum, copper, or a material containing aluminum or copper.

With the above-described structure, the heat generated from the control assembly 300 may be sequentially transferred to the control chip 320, the shield cover 400, the heat transfer member 500, and the back cover 600 and finally discharged to the atmosphere through the back cover 600, thereby suppressing the overheating of the display apparatus.

Meanwhile, although not shown, a frame coupled to edges of the display apparatus may be provided as needed. The frame may be coupled to the display apparatus to close side surfaces of the display apparatus.

Meanwhile, heat generated from the control assembly 300 may be transferred downward, that is, toward the display unit 100. The heat generated from the control assembly 300 may be transferred to the display unit 100 provided thereunder through the holder 200.

When the heat generated from the control assembly 300 is transferred to the display unit 100, the display unit 100 may overheat, thereby degrading operating performance. Meanwhile, heat transfer by conduction accounts for the largest proportion compared to convection or radiation.

Therefore, it is necessary to suppress the overheating of the display unit 100 by suppressing the heat transfer from the control assembly 300 to the display unit 100 by conduction, and to this end, the control board 310 of the control assembly 300 and the holder 200 need to be spaced apart from each other in a vertical direction. A component that plays this role is the support member 700.

The support member 700 may be attached to the holder 200 to support the control board 310 and may separate the control assembly 300 and the holder 200 in the vertical direction.

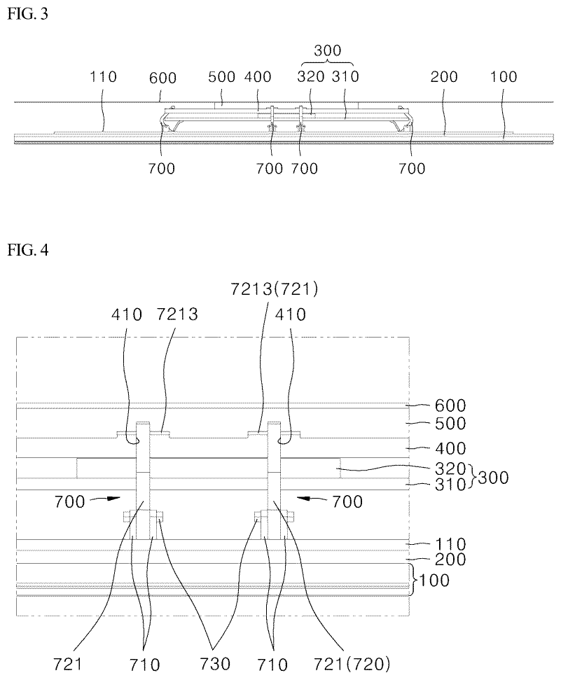

FIG. 3 is a front view showing the display apparatus according to one embodiment. FIG. 4 is an enlarged view of a portion of FIG. 3.

The support member 700 may be disposed between the holder 200 and the control board 310 to separate the holder 200 and the control board 310, thereby effectively suppressing the heat transfer by conduction due to contact between the holder 200 and the control board 310.

The support member 700 may have a three-dimensional shape. Therefore, the support member 700 may be easily manufactured by injection molding, and at the same time, is appropriately made of a material having low thermal conductivity to suppress the heat transfer by conduction between the holder 200 and the control board 310. For example, the support member 700 may be made of a plastic material.

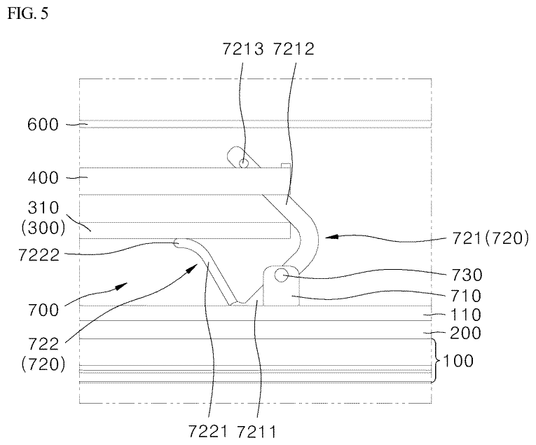

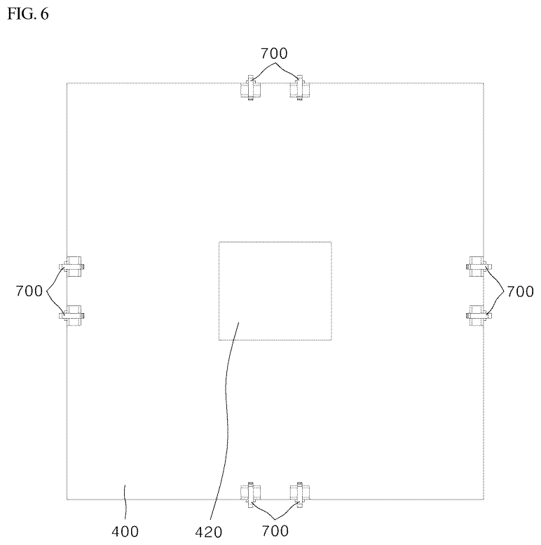

FIG. 5 is an enlarged view of another portion of FIG. 3. FIG. 6 is a view in which some components of the display apparatus according to one embodiment have been omitted.

A plurality of support members 700 may be disposed at each side of the control board 310. Referring to FIG. 6, at least one support member 700 may be disposed at each side of the control board 310 formed in a quadrangular shape to stably support the control board 310.

In the embodiment shown in FIG. 6, the total of eight support members 700 in which two are disposed at each side of the control board 310 are disposed, but the present disclosure is not limited thereto, and one or more support members 700 may be disposed at each side of the control board 310, and the number thereof may be selected appropriately.

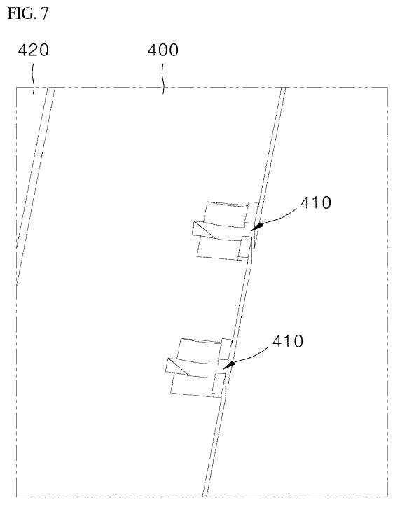

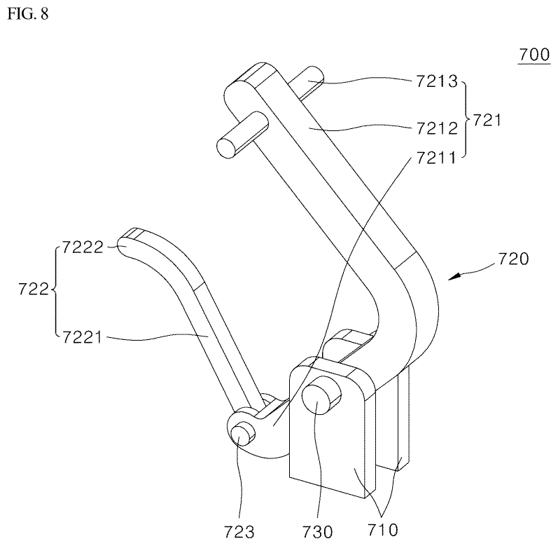

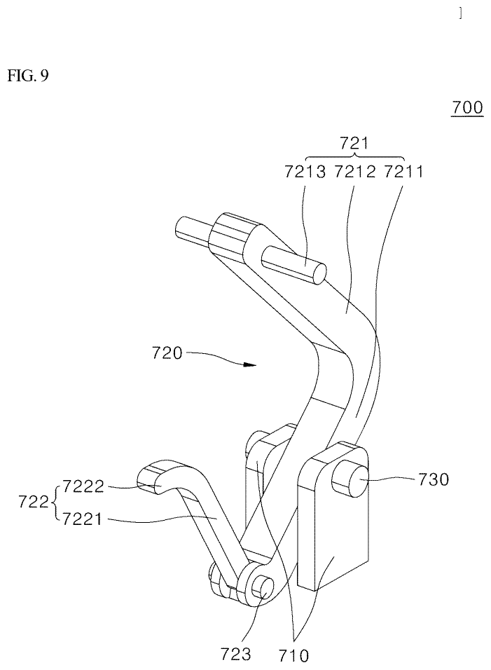

FIG. 7 is an enlarged view of a portion in which an insertion groove 410 is formed of the shield cover 400 according to one embodiment. FIG. 8 is a perspective view showing the support member 700 according to one embodiment. FIG. 9 is a view of FIG. 8 in another direction.

The support member 700 may support the control board 310 and may be provided to allow some components to rotate when the control board 310 is expanded by heat. Hereinafter, a structure of the support member 700 will be described in detail.

Referring to FIGS. 8 and 9, the support member 700 may include a base 710, a rotation supporter 720, and a coupling pin 730. The base 710 may be attached to the holder 200, and the rotation supporter 720 may be coupled to the base 710.

The base 710 may be formed of two pieces separately spaced apart from each other, and a space in which a portion of the rotation supporter 720 is disposed to rotate may be provided between the pieces. The base 710 may be attached to the holder 200 by, for example, an adhesive or a double-sided tape.

The rotation supporter 720 may be rotatably coupled to the base 710 to support the control board 310. When the control board 310 thermally expands, the rotation supporter 720 may support the control board 310 while rotating according to the degree of thermal expansion.

An end of the control board 310 may be provided to be in contact with the rotation supporter 720 to push the rotation supporter 720. Therefore, when the control board 310 thermally expands, the end of the control board 310 may push the rotation supporter 720, and the rotation supporter 720 may rotate accordingly.

The coupling pin 730 may rotatably couple the rotation supporter 720 to the base 710. The rotation supporter 720 and the base 710 may be coupled by the coupling pin 730, and the rotation supporter 720 may rotate with respect to the base 710. Holes into which the coupling pins 730 are fastened may each be formed at corresponding locations of the base 710 and the rotation support unit 720.

In addition, although not shown, a spring capable of restoring a rotational force of the coupling pin 730 may be provided to be inserted into the coupling pin 730.

The rotation supporter 720 may include a coupling cell 721 and a support cell 722. The coupling cell 721 may be coupled to the shield cover 400 and provided with the coupling pin 730. The coupling cell 721 is coupled to the shield cover 400, but may be free from the shield cover 400. Therefore, when the rotation supporter 720 rotates, the coupling cell 721 may move without affecting the shield cover 400.

The support cell 722 may extend from the coupling cell 721 and support a lower surface of the control board 310. The support cell 722 may be bent from one end of the coupling cell 721 and disposed upward to support the lower surface of the control board 310.

The support cell 722 may support the lower surface of the control board 310 to vertically separate the control assembly 300 and the holder 200. By vertically separating the control assembly 300 and the holder 200, it is possible to effectively block heat transfer by conduction from the control assembly 300 to the holder 200.

Meanwhile, the coupling cell 721 may be in contact with ends of side surfaces of the control board 310, and when the control board 310 thermally expands, the coupling cell 721 may be pushed by the control board 310. When the coupling cell 721 is pushed by the control board 310 to rotate, the support cell 722 also rotates accordingly to move the control board 310 up.

The coupling cell 721 may include a first part 7211 and a second part 7212. The first part 7211 may be rotatably coupled to the base 710 by the coupling pin 730 and may have a lower end portion connected to the support cell 722. When the first part 7211 rotates about the coupling pin 730 with respect to the base 710, the support cell 722 may also rotate together.

The second part 7212 may be bent from the first part 7211 and coupled to the shield cover 400. An end portion of the second cell is coupled to the shield cover 400, but may be free from the shield cover 400 to move without affecting the shield cover 400.

As shown in FIG. 7, the shield cover 400 may include the insertion groove 410 which is formed at the edge of each side and into which the second part 7212 is coupled by being inserted.

The second part 7212 may be inserted into the insertion groove 410 and may be guided by the insertion groove 410 to rotate. Since the insertion groove 410 guides a path along which the second part 7212 moves, the rotation supporter 720 may stably rotate along a set path.

The coupling cell 721 may include a restriction pin 7213 protruding to both sides of the second part 7212 and disposed on an upper surface of the shield cover 400 to restrict the rotation range of the coupling cell 721.

Referring to FIG. 5, when the restriction pin 7213 is disposed on the upper surface of the shield cover 400, the coupling cell 721 may not rotate counterclockwise any more in the drawing. With this structure, the restriction pin 7213 may restrict the counterclockwise rotation range of the coupling cell 721.

On the other hand, when the coupling cell 721 rotates clockwise in the state shown in FIG. 5, the restriction pin 7213 is spaced apart from the upper surface of the shield cover 400 and does not restrict or prevent the rotation of the coupling cell 721.

Two embodiments for the structure of the support cell 722 are proposed in the specification. First, the embodiment shown in FIGS. 8 and 9 will be described. The support cell 722 according to one embodiment may include a third part 7221 and a fourth part 7222.

The third part 7221 may have one end fixed to the coupling cell 721 by a fixing pin 723 to prevent rotation. The fixing pin 723 may firmly couple the third part 7221 with the coupling cell 721. Therefore, the third part 7221 does not rotate with respect to the coupling cell 721, and the third part 7221 and the coupling cell 721 may rotate integrally with respect to the base 710.

In addition, although not shown, the support cell 722 and the coupling cell 721 connected by the fixing pin 723 may further include a spring capable of restoring a rotational force in the connection relationship with the fixing pin 723.

The fourth part 7222 may be bent from the third part 7221 and may expand a contact area with the lower surface of the control board 310. The fourth part 7222 may be bent from the third part 7221 and disposed entirely parallel to the control board 310, and thus the contact area between the lower surface of the control board 310 and the upper surface of the fourth part 7222 may be expanded.

When the rotation supporter 720 rotates, slip may occur between the control board 310 and the support cell 722, and the lower surface of the control board 310 may be damaged due to this slip.

In an embodiment, since the fourth part 7222 having a great contact area may be provided in the support cell 722, even when the slip occurs between the control board 310 and the fourth part 7222, it is possible to effectively suppress the occurrence of the damage to the lower surface of the control board 310 due to slip.

Such a structure may be adopted, for example, when a soft material that may be damaged due to slip is applied to the lower surface of the control board 310.

FIG. 10 is a view for describing the support member 700 according to another embodiment. In subsequent drawings of FIG. 10, the side surface of the display apparatus is viewed in a direction in which no socket 110 is present, and thus the socket 110 is not shown in each drawing.

An end portion of the support cell 722, which is in contact with the lower surface of the control board 310, may be formed as a sharp edge 7223. In addition, the support cell 722 may be bent from an end portion of the first part 7211 of the coupling cell 721 and formed integrally with the first part 7211.

When the end portion of the support cell 722 is formed as the sharp edge 7223, the contact area between the support cell 722 and the lower surface of the control board 310 can be reduced. When elements, circuits, etc. are provided on the lower surface of the control board 310, it may be difficult to avoid the elements, the circuits, etc. and provide a space in which the end portion of the support cell 722 slips.

In this case, the end portion of the support cell 722 may be formed as the edge 7223 to reduce the contact area with the lower surface of the control board 310. Therefore, a space in which the support cell 722 is in contact with the lower surface of the control board 310 may be formed relatively narrow. Therefore, such a structure can increase space efficiency of the lower surface of the control board 310.

However, as described above, in the case of the type of the edge 7223, there is a possibility of damage due to the slip of the support cell 722 on the lower surface of the control board 310, and thus surface treatment capable of suppressing wear and damage at such a slip portion may be performed.

FIG. 11 is a view for describing deformation caused by heat deformation in the display apparatus when no support member 700 is present.

As shown in FIG. 11, an upward concave chip coupling part 420 in which the control chip 320 is accommodated may be formed on the lower surface of the shield cover 400. The display apparatus may include the adhesive pad 800 accommodated in the chip coupling part 420.

Since the chip coupling part 420 has the shape of a concave groove upward from the lower surface of the shield cover 400, to form such a groove, a portion corresponding to the chip coupling part 420 of the upper surface of the shield cover 400 may be provided in an upward convex shape.

In a state in which the adhesive pad 800 is accommodated in the chip coupling part 420, the adhesive pad 800 may be disposed between the control chip 320 and the shield cover 400 to couple the control chip 320 with the shield cover 400. The adhesive pad 800 may be made of an adhesive material having high thermal conductivity to smoothly transfer heat between the shield cover 400 and the control chip 320.

Meanwhile, when the display apparatus operates, the entirety of the control assembly 300 including the control board 310 and the control chip 320 may be heated. Due to such heating, thermal expansion of the plate-shaped control board 310 may occur.

Due to thermal expansion, the control board 310 may expand in a lateral direction of the display apparatus. When the control board 310 expands, an original shape of the flat control board 310 may be lost, thereby causing buckling.

Such buckling may occur in any direction, but for example, the control board 310 may buckle in a direction marked by the arrow in FIG. 11. That is, the control board 310 may be moved down due to thermal expansion.

When the control board 310 continuously buckles due to thermal expansion, the adhesive pad 800 may be separated from the shield cover 400 and/or the control chip 320. That is, due to the buckling of the control board 310, the adhesive pad 800 may be separated from the shield cover 400 and/or the control chip 320 in a state in which the upper and lower surfaces thereof are bonded to the shield cover 400 and the control chip 320.

When the adhesive pad 800 is separated from the shield cover 400 and/or the control chip 320, heat generated from the control assembly 300 may not be smoothly transferred to the back cover 600 by conduction. Therefore, the control assembly 300 may be more heated, and as a result, the operation of the display apparatus may be stopped by overheating, thereby degrading performance in various other ways.

Therefore, there is a need for a structure capable of suppressing the separation of the adhesive pad 800 of the control board 310 due to thermal expansion and efficiently transferring heat from the control assembly 300 to the back cover 600 by conduction by maintaining the contact of the adhesive pad 800 with the shield cover 400 and the control chip 320 even when the adhesive pad 800 is separated.

To solve such a problem, the display apparatus according to the embodiment may be provided with the support member 700. The operation of the support member 700 will be described in more detail below with reference to the drawings.

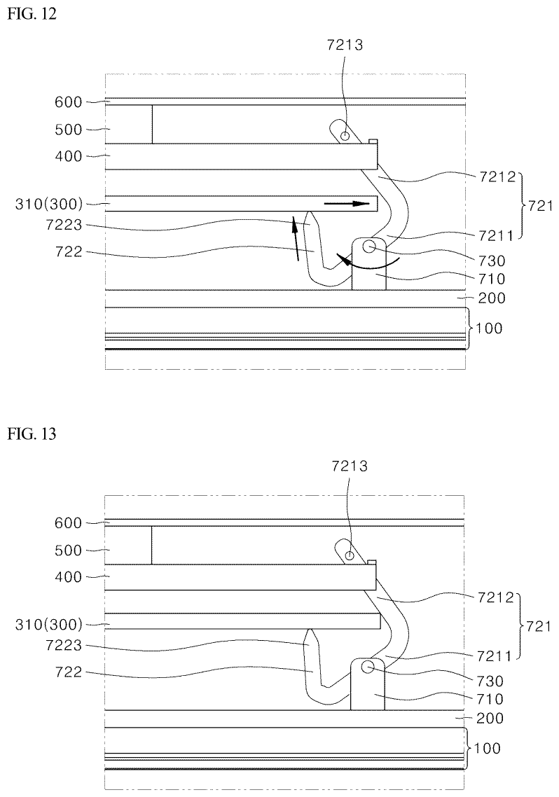

FIG. 12 is a view for describing an operation of the support member 700 according to one embodiment. FIG. 13 is a view for describing an operation of the support member 700 when the control assembly 300 is thermally deformed in FIG. 12.

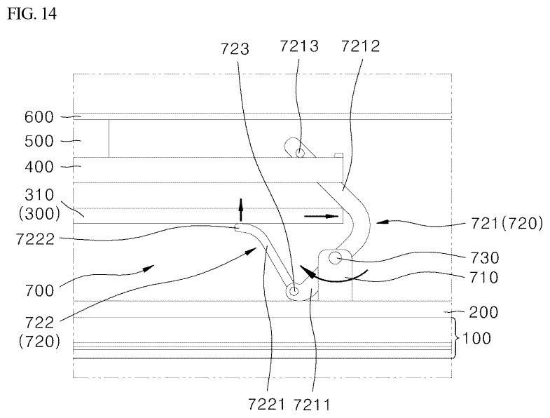

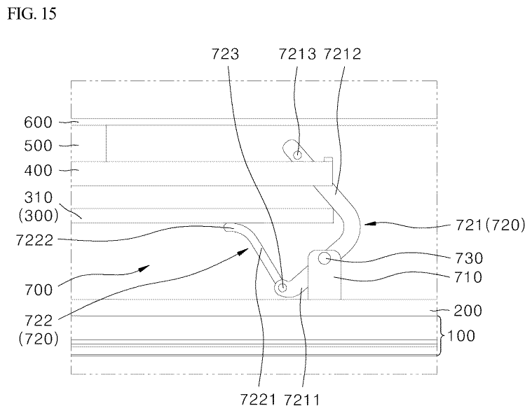

FIG. 14 is a view for describing an operation of the support member 700 according to another embodiment. FIG. 15 is a view for describing an operation of the support member 700 when the control assembly 300 is thermally deformed in FIG. 14.

Arrows shown in FIGS. 12 and 14 indicate a direction in which the control board 310 thermally expands, a rotation direction of the support member 700, and a travel direction of the support cell 722 as the display apparatus operates.

Meanwhile, FIGS. 12 and 14 show locations, that is, original locations of the support member 700 and the control assembly 300 in a state in which the control assembly 300 is not heated. Referring to the original location of the support member 700 in FIG. 12, the support member 700 is spaced apart from the holder 200. Meanwhile, in FIG. 14, referring to the original location of the support member 700, the support member 700 is in contact with an upper surface of the holder 200.

The relative arrangement state of the support member 700 and the holder 200 at the original locations may be changed depending on the design dimensions of the support member 700, the control assembly 300, and other components. That is, the relative arrangement state of the support member 700 and the holder 200 shown in FIGS. 12 and 14 is only one embodiment, and such an arrangement state may be changed depending on the design.

The rotation supporter 722 may be in contact with the lower surface of the control board 310 at the original location to support the control board 310. Therefore, the control board 310 may maintain a state of being vertically spaced apart from the holder 200, thereby effectively suppressing the heat generated from the control assembly 300 from being transferred to the display unit 100 by conduction.

When the control assembly 300 is heated, the control board 310 may laterally expand to rotate the rotation supporter 720, and the rotation supporter 720 may move the control assembly 300 up by pressing the lower surface of the control board 310.

Referring to FIGS. 12 and 14, when the display apparatus operates, the control assembly 300 for controlling the operation of the entire display apparatus may be heated by being operated. When the control board 310 and the control chip 320 of the control assembly 300 are heated, the control board 310 may thermally expand and stretch in the lateral direction of the display apparatus.

When the control assembly 300 is heated, the control board 310 may expand laterally to rotate the coupling cell 721, and the support cell 722 may rotate together with the rotation of the coupling cell 721.

In addition, when the control assembly 300 is heated, the support cell 722 may rotate and press the lower surface of the control board 310 to move the control board 310 up.

By heating the control assembly 300, the end of the control assembly 300 may expand and press the coupling cell 721 of the rotation supporter 720. When the coupling cell 721 is pressed, the rotation supporter 720 may rotate clockwise in the drawing. As the rotation supporter 720 rotates, the support cell 722 may move up, the control board 310 pressed by the support cell 722 may move up, and the entirety of the control assembly 300 may move up.

A state in which the control assembly 300 thermally expands to cause the rotation supporter 720 to rotate and the control assembly 300 to move up is shown in FIGS. 13 and 15.

When the control assembly 300 is heated, the rotation supporter 720 may maintain contact between the control assembly 300, the shield cover 400, the heat transfer member 500, and the back cover 600 by moving the control assembly 300 up.

At this time, the support cell 722 may maintain contact between the control assembly 300, the shield cover 400, the heat transfer member 500, and the back cover 600 by moving the control board 310 up.

With the above-described structure, when the control assembly 300 is heated, the control assembly 300 may be moved up by the rotation supporter 720. Since the control assembly 300 is slightly moved up by heating, it is possible to effectively suppress the adhesive pad 800 from being separated from the shield cover 400 and/or the control chip 320 even when buckling occurs due to heating.

Even when the adhesive pad 800 is separated, the control assembly 300 moves to the location moved up by heating, and thus the contact between the control assembly 300 including the control chip 320, the adhesive pad 800, the shield cover 400, the heat transfer member 500, and the back cover 600 can be maintained.

Therefore, the heat generated from the control assembly 300 can be effectively transferred to the back cover 600 by conduction and transferred from the back cover 600 to the atmosphere, thereby effectively cooling the control assembly 300 and blocking the overheating of the control assembly 300.

Meanwhile, when the operation of the display apparatus is stopped to cool the control assembly 300, the control board 310 may shrink, and the rotation supporter 720 may rotate counterclockwise, and thus the components of the display apparatus may return to the original locations shown in FIGS. 12 and 14.

A display apparatus according to one embodiment may include a display unit for displaying an image, a holder disposed above the display unit and provided in a plate shape, a control assembly disposed above the holder and including a control board and a control chip mounted on an upper surface of the control board, a shield cover disposed above the control assembly, a heat transfer member disposed above the shield cover and in contact with a portion of the shield cover, a back cover disposed above the heat transfer member and in contact with at least a portion of the heat transfer member, and a support member attached to the holder, for supporting the control board, and vertically separating the control assembly and the holder.

A plurality of support members may be disposed at each side of the control board, and the support member may include a base attached to the holder, a rotation supporter rotatably coupled to the base to support the control board, and a coupling pin rotatably coupling the rotation supporter with the base.

The rotation supporter may include a coupling cell which is coupled to the shield cover and on which the coupling pin is mounted, and a support cell extending from the coupling cell to support a lower surface of the control board.

The coupling cell may include a first part rotatably coupled to the base by the coupling pin, and a second part bent from the first part and coupled to the shield cover.

The shield cover may include an insertion groove which is formed at an edge of each side and into which the second part is coupled by being inserted.

The coupling cell may include a restriction pin protruding to both sides of the second part and disposed on an upper surface of the shield cover to restrict a rotation range of the coupling cell.

The support cell may have an end portion in contact with a lower surface of the control board formed as a sharp edge.

The support cell may include a third part having one end fixed to the coupling cell by a fixing pin to prevent rotation, and a fourth part bent from the third part and expanding a contact area with the lower surface of the control board.

When the control assembly is heated, the control board may laterally expand to rotate the rotation supporter, and the rotation supporter may move the control assembly by pressing the lower surface of the control board.

When the control assembly is heated, the rotation supporter may maintain contact between the control assembly, the shield cover, the heat transfer member, and the back cover by moving the control assembly up.

The support cell may support the lower surface of the control board to vertically separate the control assembly and the holder.

When the control assembly is heated, the control board may laterally expand to rotate the coupling cell, and the support cell may rotate together with the rotation of the coupling cell.

When the control assembly is heated, the support cell may rotate to press the lower surface of the control board and move the control board up.

The support cell may maintain contact between the control assembly, the shield cover, the heat transfer member, and the back cover by moving the control board up.

Since the support member is disposed between the holder and the control board to separate the holder and the control board, it is possible to effectively suppress the occurrence of heat transfer by conduction due to contact between the holder and the control board.

In addition, in the display apparatus according to the present disclosure, when the control assembly is heated, the control assembly can be moved up by the rotation support member. Since the control assembly is slightly moved up by heating, it is possible to effectively suppress the adhesive pad from being separated from the shield cover and/or the control chip even when buckling is caused by heating.

Even when the adhesive pad is separated, the control assembly moves to the location moved upward due to heating, and thus the contact between the control assembly including the control chip, the adhesive pad, the shield cover, the heat transfer member, and the back cover can be maintained.

Therefore, the heat generated from the control assembly can be effectively transferred to the back cover by conduction and transferred from the back cover to the atmosphere, thereby effectively cooling the control assembly and preventing overheating of the control assembly.

Specific effects together with the above-described effects are described together with a description of the following detailed matters for carrying out the invention.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising
a display unit configured to display an image;
a holder on the display unit in a plate shape;
a control assembly on the holder including a control board and a control chip mounted on an upper surface of the control board;
a shield cover on the control assembly;
a heat transfer member on the shield cover in contact with a portion of the shield cover;
a back cover on the heat transfer member in contact with at least a portion of the heat transfer member, and
a support member attached to the holder, configured to support the control board, and vertically separate the holder and the control assembly.

2. The display apparatus of claim 1, wherein the number of the support members is plural, and the support members are on each side of the control board.

3. The display apparatus of claim 1, wherein the support member includes:
a base attached to the holder;
a rotation supporter rotatably coupled to the base to support the control board; and
a coupling pin rotatably coupling the rotation supporter with the base.

4. The display apparatus of claim 3, wherein the rotation supporter includes:
a coupling cell which is coupled to the shield cover and on which the coupling pin is mounted; and
a support cell extending from the coupling cell to support a lower surface of the control board.

5. The display apparatus of claim 4, wherein the coupling cell includes:
a first part rotatably coupled to the base by the coupling pin; and
a second part bent from the first part and coupled to the shield cover.

6. The display apparatus of claim 5, wherein the shield cover includes an insertion groove which is formed at an edge of each side and into which the second part is coupled by being inserted.

7. The display apparatus of claim 5, wherein the coupling cell includes a restriction pin protruding to both sides of the second part and disposed on an upper surface of the shield cover to restrict a rotation range of the coupling cell.

8. The display apparatus of claim 5, wherein the support cell has an end portion in contact with a lower surface of the control board formed as a sharp edge.

9. The display apparatus of claim 5, wherein the support cell includes:
a third part having one end fixed to the coupling cell by a fixing pin to prevent rotation; and
a fourth part bent from the third part and expanding a contact area with the lower surface of the control board.

10. The display apparatus of claim 4, wherein, when the control assembly is heated, the control board laterally expands to rotate the rotation supporter, and the rotation supporter moves the control assembly by pressing the lower surface of the control.

11. The display apparatus of claim 10, wherein, when the control assembly is heated, the rotation supporter maintains contact between the control assembly, the shield cover, the heat transfer member, and the back cover by moving the control assembly.

12. The display apparatus of claim 4, wherein the support cell supports the lower surface of the control board to vertically separate the control assembly and the holder.

13. The display apparatus of claim 4, wherein, when the control assembly is heated, the control board may laterally expand to rotate the coupling cell, and the support cell rotates together with the rotation of the coupling.

14. The display apparatus of claim 13, wherein, when the control assembly is heated, the support cell rotates to press the lower surface of the control board and moves the control board up.

15. The display apparatus of claim 14, wherein the support cell maintains contact between the control assembly, the shield cover, the heat transfer member, and the back cover by moving the control board up.
